(19) United States
(12) Patent Application Publication
(10) Pub. No.: US 2024/0243141 A1
(43) Pub. Date: Jul. 18, 2024

(54) PHOTOELECTRIC DETECTOR, DETECTION SUBSTRATE AND MANUFACTURING METHOD THEREFOR, AND DETECTION APPARATUS

(71) Applicants: Beijing BOE Technology Development Co., Ltd., Beijing (CN); BOE Technology Group Co., Ltd., Beijing (CN)

(72) Inventor: Hu MENG, Beijing (CN)

(21) Appl. No.: 18/622,788

(22) Filed: Mar. 29, 2024

Related U.S. Application Data
(63) Continuation of application No. PCT/CN2021/140244, filed on Dec. 21, 2021.

(51) Int. Cl. H01L 27/146

(52) U.S. Cl. CPC H01L 27/1461; H01L 27/14636; H01L 27/14692

(57) ABSTRACT

Provided in the present disclosure are a photoelectric detector, a detection substrate and a manufacturing method therefor, and a detection apparatus. The photoelectric detector comprises a first electrode; a semiconductor layer, which is located on one side of the first electrode, wherein a Schottky junction is provided between the semiconductor layer and the first electrode; an intrinsic absorption layer, which is located on the side of the semiconductor layer that is away from the first electrode; and a second electrode, which is arranged opposite the first electrode, wherein the second electrode is arranged adjacent to one of the intrinsic absorption layer and the semiconductor layer.

### CROSS REFERENCE TO RELATED APPLICATIONS

The present disclosure is a continuation application of International Application of International Application No. PCT/CN2021/140244, filed Dec. 21, 2021, the entire content of which is incorporated herein by reference.

### TECHNICAL FIELD

The present disclosure relates to the field of a photoelectric detection technology, and in particular to a photoelectric detector, a detection substrate and manufacturing method therefor, and a detection apparatus.

### BACKGROUND

Photoelectric detectors can be used in large-area X-ray detection, fingerprint recognition, palmprint recognition and other fields, and are increasingly playing an important role in the national economy and people's livelihood. The photoelectric detectors have the advantages of large-area preparation, simple process, and low cost, and have broad application prospects.

### SUMMARY

A photoelectric detector, a detection substrate, a method for manufacturing a detection substrate and a detection apparatus provided by the present disclosure are as follows.

In one aspect, embodiments of the present disclosure provide a photoelectric detector, including:
a first electrode;
a semiconductor layer located on a side of the first electrode, and there is a Schottky junction between the semiconductor layer and the first electrode;
an intrinsic absorption layer located on a side of the semiconductor layer away from the first electrode; and
a second electrode being opposite to the first electrode, and the second electrode is adjacent to one of the intrinsic absorption layer and the semiconductor layer.

In some embodiments, in the photoelectric detector provided by the embodiments of the present disclosure, the second electrode and the first electrode are arranged in different layers and opposite to each other, and the second electrode is arranged adjacent to the intrinsic absorption layer.

In some embodiments, in the photoelectric detector provided by the embodiments of the present disclosure, the second electrode is arranged opposite to the first electrode in the same layer, the second electrode is arranged adjacent to the semiconductor layer, and the second electrode and the first electrode form an interdigitated electrode.

In some embodiments, the photoelectric detector provided by the embodiments of the present disclosure, further includes an active layer disposed between the semiconductor layer and the intrinsic absorption layer.

In some embodiments, in the photoelectric detector provided by the embodiments of the present disclosure, an orthographic projection of the active layer on the first electrode, an orthographic projection of the semiconductor layer on the first electrode, and an orthographic projection of the intrinsic absorption layer on the first electrode are substantially coincident, and an area of the orthographic projection of the active layer on the first electrode is larger than an area of an interdigital region of the interdigitated electrode.

In some embodiments, in the photoelectric detector provided by the embodiments of the present disclosure, a material of the active layer is oxide.

In some embodiments, in the photoelectric detector provided by the embodiments of the present disclosure, a material of the first electrode includes a metal material and/or a semi-metallic material.

In some embodiments, in the photoelectric detector provided by the embodiments of the present disclosure, the metal material is stacked titanium metal and palladium metal, and the semi-metallic material is graphene.

In some embodiments, in the photoelectric detector provided by the embodiments of the present disclosure, a material of the semiconductor layer is indium gallium zinc oxide or polysilicon.

In some embodiments, in the photoelectric detector provided by the embodiments of the present disclosure, a material of the intrinsic absorption layer is cadmium selenide/zinc sulfide quantum dots or lead sulfide quantum dots.

In some embodiments, in the photoelectric detector provided by the embodiments of the present disclosure, a material of the second electrode is a transparent conductive material.

In some embodiments, in the photoelectric detector provided by the embodiments of the present disclosure, the transparent conductive material is indium tin oxide.

In another aspect, the embodiments of the present disclosure provide a detection substrate, including:
a base substrate;
a plurality of photoelectric detectors arranged in an array on the base substrate, and the photoelectric detectors are photoelectric detectors according to any one of above embodiments.

In some embodiments, the detection substrate provided by the embodiments of the present disclosure, further includes a plurality of transistors, a layer where the plurality of transistors are located is between the base substrate and a layer where the plurality of photoelectric detectors are located, first electrodes of the transistors are electrically connected with the first electrodes in a one-to-one correspondence.

In some embodiments, the detection substrate provided by the embodiments of the present disclosure, further includes a plurality of gate lines and a plurality of data lines arranged in an intersecting manner, the plurality of gate lines and the plurality of data lines intersects, wherein each of the plurality of gate lines is electrically connected with gates of transistors corresponding to a row of photoelectric detectors in an extending direction of the gate lines, each of the plurality of data lines is electrically connected with second electrodes of transistors corresponding to a row of photoelectric detectors in an extending direction of the data lines.

In some embodiments, in the detection substrate provided by the embodiments of the present disclosure, orthographic projections of the plurality of gate lines on the base substrate and orthographic projections of the plurality of photoelectric detectors on the base substrate do not overlap each other, orthographic projections of the plurality of data lines on the base substrate and the orthographic projections of the plurality of photoelectric detectors on the base substrate do not overlap each other.

In some embodiments, the detection substrate provided by the embodiments of the present disclosure, further includes a plurality of bias-voltage lines, a layer where the plurality of bias-voltage lines are located is on a side of a layer where the plurality of photoelectric detectors are located away from the base substrate, wherein the plurality of bias-voltage lines are arranged in parallel with the plurality of data lines or the plurality of gate lines, and each of the plurality of bias-voltage lines is electrically connected with the second electrodes of a row of the photoelectric detectors correspondingly in an extending direction of the plurality of bias-voltage lines.

In another aspect, the embodiments of the present disclosure provide a method for manufacturing the aforementioned detection substrate, including:
providing a base substrate;
forming a plurality of photoelectric detectors arranged in an array on the base substrate, and the plurality of photoelectric detectors are the photoelectric detectors according to any one of above embodiments.

In some embodiments, in the method provided by the embodiments of the present disclosure, the forming a plurality of photoelectric detectors arranged in an array on the base substrate, includes:
forming a plurality of first electrodes arranged in an array on the base substrate;
forming a semiconductor layer correspondingly on each of the plurality of first electrodes; and
forming an intrinsic absorption layer and a second electrode correspondingly on the semiconductor layer;
where the first electrode, the semiconductor layer, the intrinsic absorption layer and the second electrode which are arranged correspondingly form a photoelectric detector.

In some embodiments, in the method provided by some embodiments of the present disclosure, the forming a plurality of photoelectric detectors arranged in an array on the base substrate, includes:
forming a plurality of first electrodes and a plurality of second electrodes on the base substrate, where the first electrodes are in one-to-one correspondence with the second electrodes to form interdigitated electrodes;
forming a semiconductor layer correspondingly on each of the interdigitated electrodes; and
forming an active layer and an intrinsic absorption layer correspondingly on the semiconductor layer;
where the interdigitated electrode, the semiconductor layer, the active layer and the intrinsic absorption layer which are arranged correspondingly form a photoelectric detector.

In another aspect, the embodiments of the present disclosure provide a detection apparatus, including the detection substrate according to any one of above embodiments.

### BRIEF DESCRIPTION OF FIGURES

FIG. 1 is a schematic structural diagram of a photoelectric detector provided by an embodiment of the present disclosure.

FIG. 2 is a working principle diagram of the photoelectric detector shown in FIG. 1.

FIG. 3 is another structural schematic diagram of a photoelectric detector provided by an embodiment of the present disclosure.

FIG. 4 is a schematic structural diagram of the first electrode and the second electrode in FIG. 3.

FIG. 5 is a sectional view along line I-II in FIG. 3.

FIG. 6 is a working principle diagram of the photoelectric detector shown in FIG. 3.

FIG. 7 is another working principle diagram of the photoelectric detector shown in FIG. 3.

FIG. 8 shows a volt-ampere curve of the photoelectric detector shown in FIG. 1.

FIG. 9 shows an external quantum efficiency curve of photoelectric detector shown in FIG. 3.

FIG. 10 shows a volt-ampere curve of the photoelectric detector shown in FIG. 3.

FIG. 11 is a schematic structural diagram of a detection substrate provided by an embodiment of the present disclosure.

FIG. 12 is a sectional view along line III-IV in FIG. 4.

FIG. 13 is another schematic structural diagram of a detection substrate provided by an embodiment of the present disclosure.

### DETAILED DESCRIPTION

In order to make the objectives, technical solutions and advantages of the embodiments of the present disclosure clearer, the technical solutions of the embodiments of the present disclosure will be clearly and completely described below in conjunction with the drawings of the embodiments of the present disclosure. It should be noted that the size and shape of each figure in the drawings do not reflect the true scale, but are only intended to illustrate the present disclosure. And the same or similar reference numerals represent the same or similar elements or elements having the same or similar functions throughout.

Unless otherwise defined, the technical terms or scientific terms used herein shall have the usual meanings understood by those having ordinary skill in the art to which the present disclosure belongs. “First”, “second” and similar words used in the present disclosure and claims do not indicate any order, quantity or importance, but are only used to distinguish different components. “Comprise” or “include” and similar words mean that the elements or items appearing before the word include the elements or items listed after the word and their equivalents, without excluding other elements or items. “Inner”, “outer”, “upper”, “lower” and so on are only used to indicate relative positional relationship. When the absolute position of the described object changes, the relative positional relationship may also change accordingly.

In the related art, a commonly used photoelectric detector includes a bottom electrode, a photoelectric conversion layer, and a top electrode, which are stacked. The photoelectric conversion layer includes a P-type semiconductor layer, an intrinsic semiconductor layer, and an N-type semiconductor layer, which are stacked. The material of the P-type semiconductor layer is amorphous silicon (a-Si) material doped with donor impurities. The material of the N-type semiconductor layer is a-Si material doped with acceptor impurities, and the material of the intrinsic semiconductor layer is a-Si. The external quantum efficiency (EQE) of this photoelectric detector is about 60% to 70%, and it is limited by the carrier diffusion process in the P region and the N region, as well as the defect trapping in the a-Si material. The response speed of this kind of photoelectric detector is low.

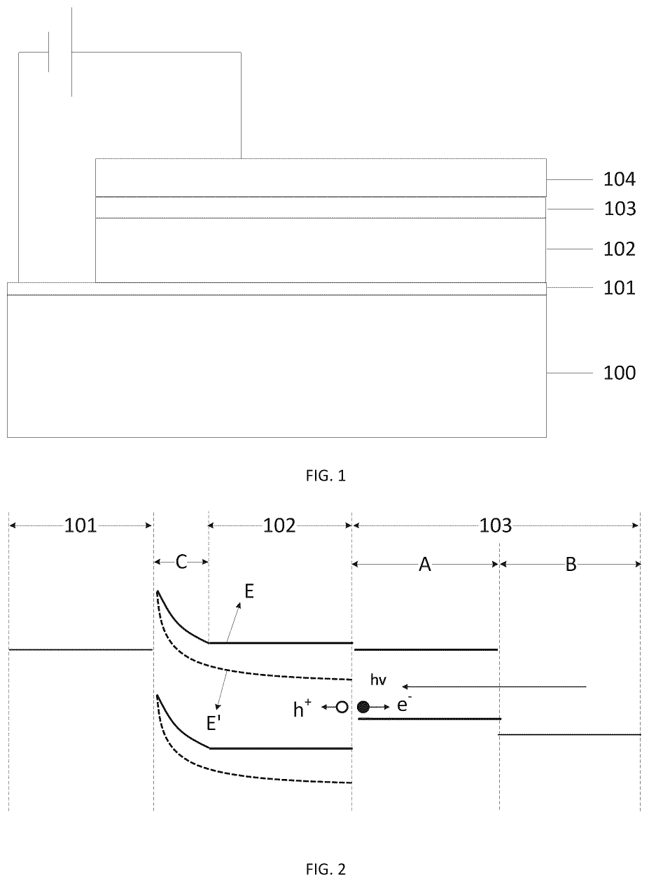

To solve the above-mentioned technical problems existing in related art, the embodiments of the present disclosure provides a photoelectric detector, as shown in FIG. 1, including:
a first electrode 101;
a semiconductor layer 102 located on a side of the first electrode 101, and a Schottky junction is provided between the semiconductor layer 102 and the first electrode 101;
an intrinsic absorption layer 103 located on a side of the semiconductor layer 102 away from the first electrode 101; and
a second electrode 104 opposite to the first electrode 101, and the second electrode 104 is disposed adjacent to one of the intrinsic absorption layer 103 and the semiconductor layer 102.

In the above-mentioned photoelectric detector provided by the embodiments of the present disclosure, electron-hole pairs are generated by the intrinsic absorption layer 103 after absorbing light energy (hv). The photoelectric detector can not only have a faster response speed, but also generate an internal current gain and obtain a higher external quantum efficiency, based on the combined effect of the electric field applied by the first electrode 101 and the second electrode 104, and the built-in electric field of the Schottky junction.

In some embodiments, in the above-mentioned photoelectric detector provided by the embodiments of the present disclosure, as shown in FIG. 1, the second electrode 104 and the first electrode 101 are arranged in different layers and opposite to each other, and the second electrode 104 is adjacent to the intrinsic absorption layer 103. In a photoelectric detector with such a structure, as shown in FIG. 2, after the intrinsic absorption layer 103 absorbs light energy (hv), a hole h⁺ and an electron e are generated in a space-charge region A and an intrinsic region B of the intrinsic absorption layer 103. Under the action of an external electric field applied by the first electrode 101 and the second electrode 104, the electron e⁻ passes through the intrinsic region B of the intrinsic absorption layer 103 and is collected by the second electrode 104. There is a space-charge region C of the Schottky junction between the first electrode 101 and the semiconductor layer 102, and the bottom of the conduction band formed by the built-in electric field of the Schottky junction is E. After the external electric field applied by the first electrode 101 and the second electrode 104 is superposed, an internal electric field of a reverse Schottky junction is formed, and the bottom of the conduction band is reduced to E′, so that the hole h⁺ is rapidly swept out by the drift of the space-charge region A of the intrinsic absorption layer 103 and the internal electric field of the reverse Schottky junction. Due to the strong effect of the internal electric field of the Schottky junction and the shorter transmission distance of hole h⁺ and the electron e⁻ in a vertical direction, the photoelectric detector has a faster response speed as a whole. Further, due to the arrangement of the asymmetric structure (that is, the different transport mechanisms of the hole h⁺ and the electron e⁻), the difference in the sweep-out speed of photogenerated hole h⁺ and electron e⁻ during the illumination process forms a carrier accumulation effect, and the photoelectric detector generates an internal current gain, enabling photodetection with high external quantum efficiency.

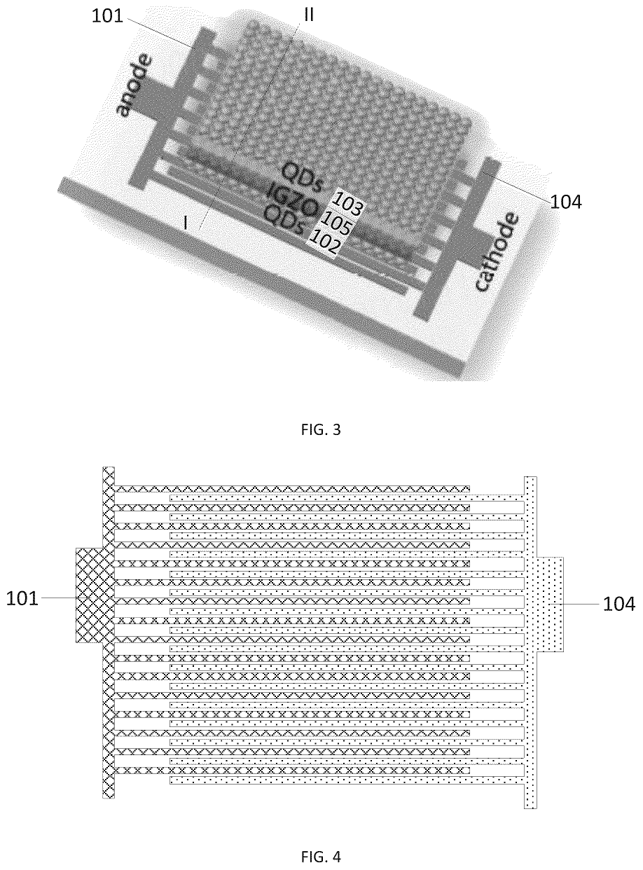

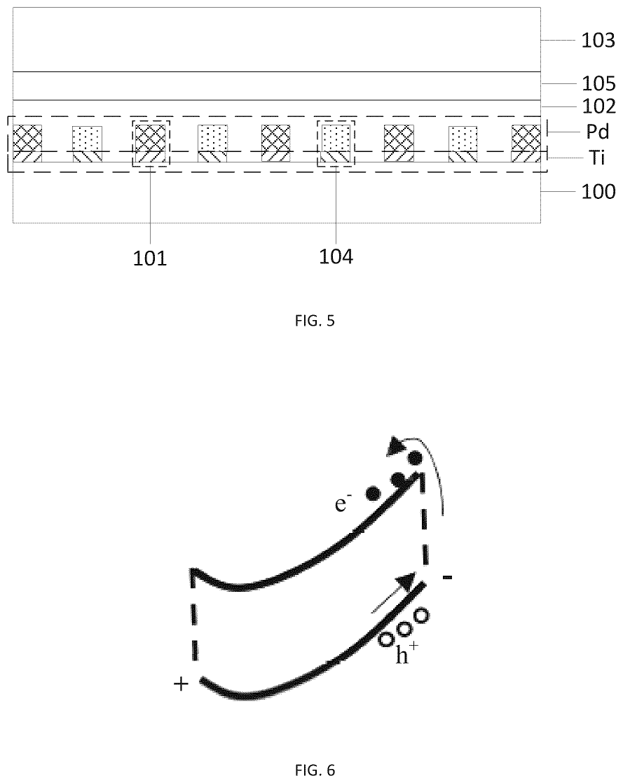

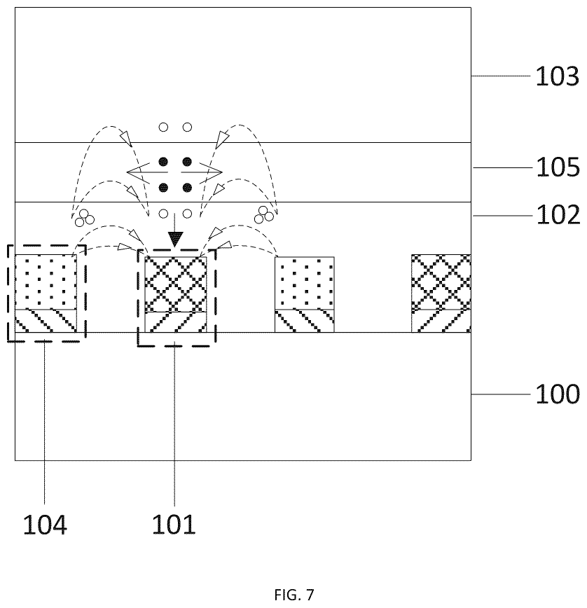

In some embodiments, in the above-mentioned photoelectric detector provided by the embodiments of the present disclosure, as shown in FIG. 3 to FIG. 5, the second electrode 104 and the first electrode 101 are arranged in the same layer and opposite to each other, and the second electrode 104 is adjacent to the semiconductor layer 102. The second electrode 104 and the first electrode 101 form an interdigitated electrode. In the photoelectric detector with this structure, as shown in FIG. 6 and FIG. 7, the intrinsic absorption layer 103 absorbs light energy (hv) and generates electron e⁻-hole h⁺ pairs. The electrons e⁻ drift and are transported under the action of the transverse electric field of the interdigitated electrode, and are collected by half of the interdigitated electrode. The holes h⁺ are divided into two parts: one part drifts through the built-in electric field of the Schottky junction, and is collected by the other half of the interdigitated electrode, so it has a faster response speed; the other part accumulates in the semiconductor layer 102 to generate internal current gain, while realizing photodetection with high external quantum efficiency.

In some embodiments, the above-mentioned photoelectric detectors provided by the embodiments of the present disclosure, as shown in FIG. 3 and FIG. 5, may further include an active layer 105 which is arranged between the semiconductor layer 102 and the intrinsic absorption layer 103, so as to facilitate the transmission of electrons e⁻ and holes h⁺ to the interdigitated electrode through the active layer 105.

In some embodiments, in the above-mentioned photoelectric detector provided by the embodiments of the present disclosure, as shown in FIG. 3, an orthographic projection of the active layer 105 on the first electrode 101, an orthographic projection of the semiconductor layer 102 on the first electrode 101, and an orthographic projection of the intrinsic absorption layer 103 on the first electrode 101 roughly coincide (that is, just coincide, or within the error range caused by factors such as manufacturing process and measurement), and an area of the orthographic projection of the active layer 105 on the first electrode 101 can be larger than an area of the interdigital region of the interdigitated electrode, so as to enhance the response speed of the photoelectric detector to light energy.

In some embodiments, in the above-mentioned photoelectric detector provided by the embodiments of the present disclosure, a material of the active layer 105 can be an oxide, such as indium gallium zinc oxide (IGZO), so that the photoelectric detector has a lower leakage current.

In some embodiments, in the above-mentioned photoelectric detector provided by the embodiments of the present disclosure, a material of the first electrode 101 may include a metal material and/or a semi-metallic material, so as to facilitate to form the Schottky junction at the contact surface between the first electrode 101 and the semiconductor layer 102. Optionally, the metal material can be titanium (Ti) metal and palladium (Pd) metal, etc., which are stacked. The palladium metal is in contact with the semiconductor layer 102, and the titanium metal is used as an adhesion layer. In some embodiments, the titanium metal can be replaced with metals such as gold (Au) and platinum (Pt). The semi-metallic material can be graphene, such as single-layer graphene.

In some embodiments, in the above-mentioned photoelectric detector provided by the embodiments of the present disclosure, a material of the semiconductor layer 102 in the present disclosure is different from a-Si material in the related art, and the material of the semiconductor layer 102 in the present disclosure is indium gallium zinc oxide (IGZO) or polysilicon (p-Si). The semiconductor layer 102 made of indium gallium zinc oxide (IGZO) or polysilicon (p-Si) material can form the Schottky junction well with the first electrode 101 at the contact surface therebetween on the one hand, and on the other hand, compared with the semiconductor layer 102 made of the a-Si material, the semiconductor layer 102 made of IGZO has fewer defects, which greatly reduces trapping the holes h⁺ generated by the intrinsic absorption layer 103, so that the holes h⁺ generated by the intrinsic absorption layer 103 can drift faster to the first electrode 101.

In some embodiments, in the above-mentioned photoelectric detector provided by the embodiments of the present disclosure, a material of the intrinsic absorption layer 103 can be cadmium selenide/zinc sulfide quantum dots (CdSe/ZnS QD) or lead sulfide quantum dots (PbS QD) and other quantum dots (QDs) with high photoelectric absorption efficiency and good stability.

In some embodiments, in the above-mentioned photoelectric detector provided by the embodiments of the present disclosure, the material of the second electrode 104 can be a transparent conductive material, so that light can pass through the second electrode 104 and irradiate the intrinsic absorption layer 103. Optionally, the transparent conductive material is indium tin oxide (ITO) or the like.

Optionally, the embodiments of the present disclosure provide photoelectric detectors with three specific structures. The first electrode 101 and the second electrode 104 of the first type of photoelectric detector are opposite to each other in different layers, and the material of the first electrode 101 are titanium metal and palladium metal which are stacked. The thickness of titanium metal is greater than or equal to 30 Å and less than or equal to 50 Å. The thickness of palladium metal is greater than or equal to 400 Å and less than or equal to 500 Å. The material of the semiconductor layer 102 is indium gallium zinc oxide. The thickness of the semiconductor layer 102 is greater than or equal to 50 nm and less than or equal to 100 nm. The material of the intrinsic absorption layer 103 is cadmium selenide/zinc sulfide quantum dots, and the thickness of the intrinsic absorption layer 103 is greater than or equal to 50 nm and less than or equal to 70 nm. The material of the second electrode 104 is indium tin oxide, the thickness of the second electrode 104 is greater than or equal to 70 nm and less than or equal to 140 nm. The first electrode 101 and the second electrode 104 of the second type of photoelectric detector are opposite to each other in different layers. The material of the first electrode 101 is graphene, and the thickness of the first electrode 101 is greater than 0 nm and less than or equal to 1 nm. The material of the semiconductor layer 102 is polycrystalline silicon, the thickness of the semiconductor layer 102 is greater than or equal to 50 nm and less than or equal to 100 nm. The material of the intrinsic absorption layer 103 is lead sulfide quantum dots, and the thickness of the intrinsic absorption layer 103 is greater than or equal to 50 nm and less than or equal to 70 nm. The material of the second electrode 104 is indium tin oxide, and the thickness of the second electrode 104 is greater than or equal to 70 nm and less than or equal to 140 nm. The first electrode 101 and the second electrode 104 of the third type of photoelectric detector are opposite to each other in the same layer to form an interdigitated electrode. A finger width of the interdigitated electrode is greater than or equal to 3 μm and less than or equal to 15 μm, and finger spacing of the interdigitated electrode is greater than or equal to 5 μm and less than or equal to 30 μm. The material of the first electrode 101 is titanium metal and palladium metal which are stacked, the thickness of the titanium metal is greater than or equal to 5 nm and less than or equal to 10 nm, the thickness of the palladium metal is greater than or equal to 40 nm and less than or equal to 200 nm. The materials of the semiconductor layer 102 and the intrinsic absorption layer 103 are all cadmium selenide/zinc sulfide quantum dots. The material of the active layer 105 is indium gallium zinc oxide, and the thickness of the active layer 105 is greater than or equal to 30 nm and less than or equal to 100 nm.

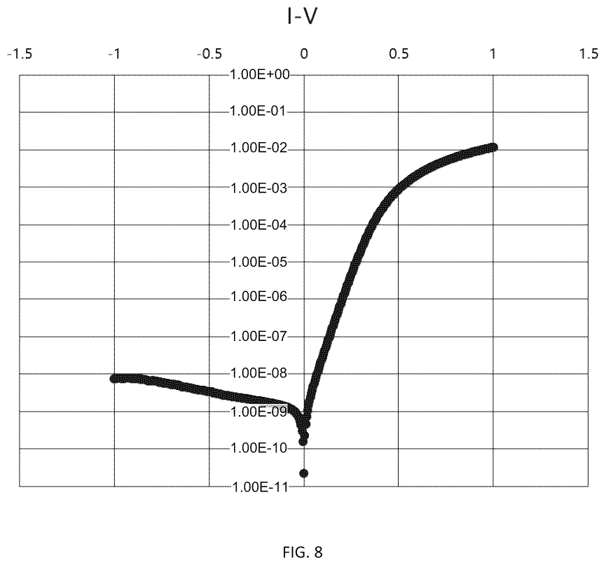

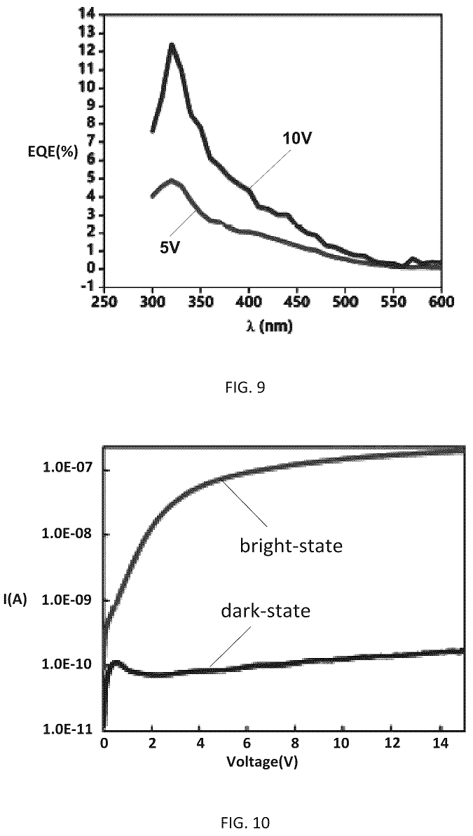

Further, the present disclosure provides the volt-ampere (I-V) curve of the first type of photoelectric detector, as shown in FIG. 8, and the external quantum efficiency curve and volt-ampere (I-V) curve of the third type of photoelectric detector, as shown in FIG. 9 and FIG. 10. As shown in FIG. 8, the abscissae is the voltage (V), and the ordinate is the current (I). It can be seen from FIG. 8 that the direction of the external electric field is the same as that of the built-in electric field of the Schottky junction under a negative voltage, and the direction of the two is opposite under a positive voltage. For the first type of photoelectric detector, it needs to be driven with a negative bias voltage to reduce the dark-state current. It can be seen from FIG. 9 and FIG. 10 that the third type of photoelectric detector has a lower dark-state leakage current and a higher bright-state current under a positive bias voltage, and needs to be driven with the positive bias voltage.

Based on the same inventive concept, the embodiments of the present disclosure provide a detection substrate. Since the problem-solving principle of the detection substrate is similar to that of the photoelectric detector above, the implementation of the detection substrate provided by the embodiments of the present disclosure can be found in the implementation of the above-mentioned photoelectric detector provided by the embodiments of the present disclosure and will not be described repeatedly.

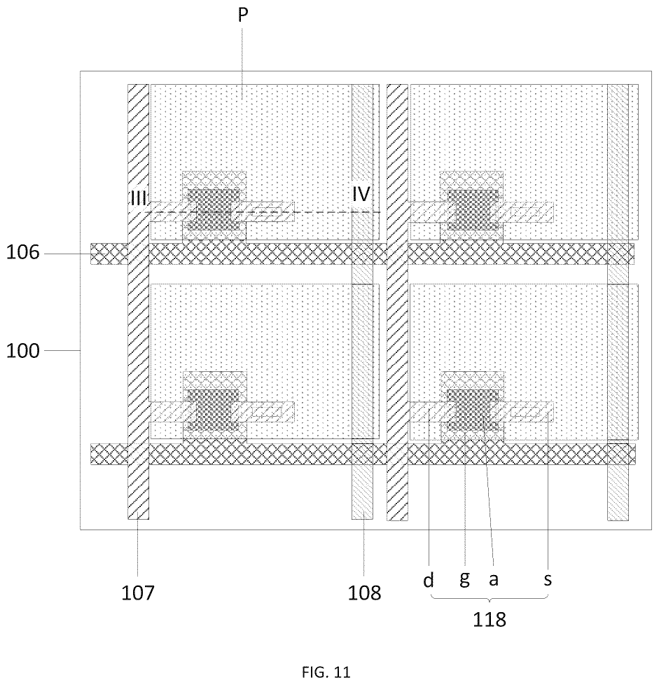

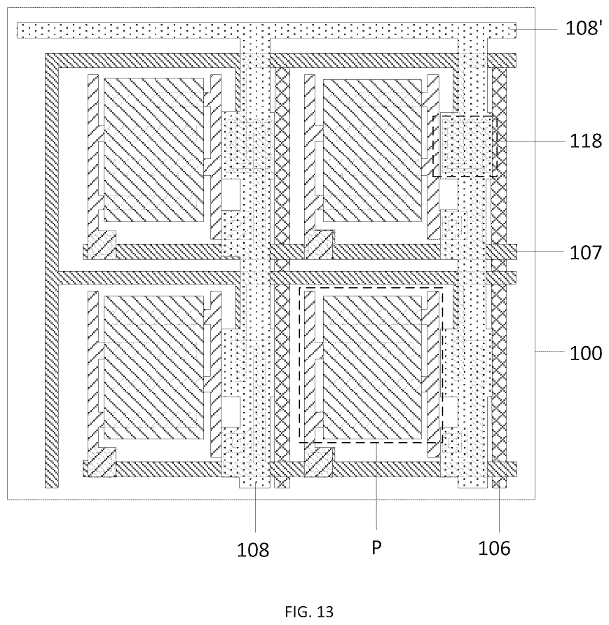

Specifically, a detection substrate provided by the embodiments of the present disclosure, as shown in FIG. 11 to FIG. 13, includes:
a base substrate 100; and
a plurality of photoelectric detectors P arranged in an array on the base substrate 100 (FIG. 11 and FIG. 13 only illustrate 2*2 photoelectric detectors P), and the photoelectric detectors P are the photoelectric detector provided by the above embodiments of the present disclosure.

In some embodiments, the detection substrate provided by the embodiments of the present disclosure, as shown in FIG. 11 to FIG. 13, may further include a plurality of transistors 118. A layer where the transistors 118 are located is disposed between the base substrate 100 and a layer where the photoelectric detectors P are located. The first electrodes s of the transistors 118 are electrically connected with the first electrodes 101 in a one-to-one correspondence. Optionally, as shown in FIG. 11, an orthographic projection of a transistor 118 on the base substrate 100 is located within an orthographic projection of a corresponding photoelectric detector P on the base substrate 100, which effectively improves a filling rate of a detection pixel. As shown in FIG. 13, the orthographic projection of the transistor 118 on the base substrate 100 does not overlap with the orthographic projection of the corresponding photoelectric detector P on the base substrate 100, so as to reduce the influence of noise generated by the transistor 118 on the photoelectric detection. In actual implementation, the relative positions of the transistor 118 and the photoelectric detector P can be flexibly set according to actual needs, which is not specifically limited here.

In some embodiments, the detection substrate provided by the embodiments of the present disclosure, as shown in FIG. 11 and FIG. 13, may further include a plurality of gate lines 106 and a plurality of data lines 107 that are arranged in an intersecting manner. Each of the gate lines 106 is electrically connected with gates g of the transistors 118 corresponding to a row of photoelectric detectors P, and each of the data lines 107 is electrically connected with second electrodes d of transistors 118 corresponding to a column of photoelectric detectors P. In order to simplify the manufacturing process, save the manufacturing cost, and improve the production efficiency, the gate lines 106 and the gates g electrically connected thereto can be prepared at the same time by using one patterning process, and the data lines 107 and the second electrodes d and the first electrodes s electrically connected thereto can also be prepared at the same time by one patterning process.

Optionally, the material of the active layer a of the transistor 118 may be amorphous silicon, polysilicon, oxide, etc., which is not limited herein. The transistor 118 may be a top-gate transistor, a bottom-gate transistor, or a double-gate transistor, etc., which is not limited here. The first electrode s of the transistor 118 is the source, and the second electrode d of the transistor 118 is the drain, or the first electrode s of the transistor 118 is the drain, and the second electrode d of the transistor 118 is the source, and no specific distinction is made here.

In some embodiments, in the detection substrate provided by the embodiments of the present disclosure, as shown in FIG. 11 and FIG. 13, the orthographic projections of the gate lines 106 on the base substrate 100 do not overlap the orthographic projections of the photoelectric detectors P. The orthographic projections of the data lines 107 on the base substrate 100 do not overlap the orthographic projections of the photoelectric detectors P on the base substrate 100. In this way, the coupling capacitance formed between the photoelectric detectors P and the gate lines 106 and the data lines 107 can be avoided, thereby effectively improving the signal-to-noise ratio.

In some embodiments, the detection substrate provided by the embodiments of the present disclosure, as shown in FIG. 11 and FIG. 13, may further include a plurality of bias-voltage lines 108. A layer where the bias-voltage lines 108 are located is at a side of the layer where the photoelectric detectors P are located away from the base substrate 100. The bias-voltage lines 108 are arranged in parallel with the data lines 107 or the gate lines 106 (that is, the extending direction of the bias-voltage lines 108 is the same with that of the data lines 107 or that of the gate lines 106). Each of the bias-voltage lines 108 is electrically connected with the second electrodes 104 of a row of photoelectric detectors P correspondingly. Optionally, the bias-voltage line 108 may be made of a transparent conductive material, such as indium tin oxide (ITO) etc., or a metal material, such as copper, silver, or the like. When a transparent conductive material is used, a bias-voltage line 108 overlapped with the photoelectric detector P will not block light, and the filling rate can be effectively improved. Optionally, a bias voltage can be uniformly applied to each bias-voltage line 108 through a bias-voltage wire 108′ around the display area AA.

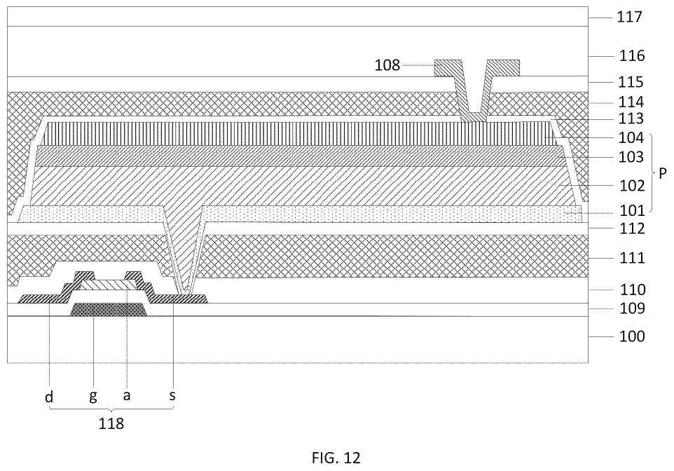

In some embodiments, the detection substrate provided by the embodiments of the present disclosure, as shown in FIG. 12, may further include: a gate insulating layer 109, a first insulating layer 110, a first planarization layer 111, a second insulating layer 112, a protective layer 113, a second planarization layer 114, the third insulating layer 115, the third planarization layer 116 and a shielding electrode 117, etc. Other essential components for the detection substrate should be understood by those having ordinary skill in the art, which will not be described in detail here, nor should it be used as a limitation on the present disclosure.

Correspondingly, the present disclosure provides a method for manufacturing the above detection substrate provided by the embodiments of the present disclosure, including the following steps:
providing a base substrate; and
forming a plurality of photoelectric detectors arranged in an array on the base substrate, and the photoelectric detectors are the above-mentioned photoelectric detectors provided by the embodiments of the present disclosure.

In some embodiments, in the above manufacturing method provided by the embodiments of the present disclosure, the forming the plurality of photoelectric detectors arranged in an array on the base substrate, which can be specifically implemented in the following two ways.

The first implementation way includes the following steps:
forming a plurality of first electrodes arranged in an array on the base substrate;
forming a semiconductor layer on each first electrode correspondingly; and
forming an intrinsic absorption layer and a second electrode correspondingly on each semiconductor layer;
here, the first electrode, the semiconductor layer, the intrinsic absorption layer and the second electrode arranged correspondingly form a photoelectric detector.

The second implementation way includes the following steps:
forming a plurality of first electrodes and a plurality of second electrodes on the base substrate, where the first electrodes are in one-to-one correspondence with the second electrodes to form interdigitated electrodes;
forming a semiconductor layer correspondingly on each interdigitated electrode; and
forming an active layer and an intrinsic absorption layer correspondingly on each semiconductor layer;
here, the interdigitated electrode, the semiconductor layer, the active layer and the intrinsic absorption layer arranged correspondingly form a photoelectric detector.

To better understand the above manufacturing method provided by the embodiments of the present disclosure, the manufacturing processes of the three types of detection substrates will be described in detail below.

In the first type of detection substrate, the material of the first electrode 101 of the photoelectric detector is stacked titanium metal and palladium metal, the material of the semiconductor layer 102 is indium gallium zinc oxide, the material of the intrinsic absorption layer 103 is cadmium selenide/zinc sulfide quantum dots, the material of the second electrode 104 is indium tin oxide, and the corresponding manufacturing process is as follows.
(1) Forming a titanium metal layer with a thickness greater than or equal to 30 Å and less than or equal to 50 Å on the base substrate 100 by a magnetron sputtering process, and forming a palladium metal layer with a thickness greater than or equal to 400 Å and less than or equal to 500 Å on the titanium metal layer.
(2) Coating photoresist on the palladium metal layer, and photo-etching and developing the photoresist to pattern the photoresist, to obtain a photoresist pattern for making the first electrode 101.
(3) Etching the stacked titanium metal layer and palladium metal layer by using the photoresist pattern as a mask, to form a plurality of first electrodes 101 arranged in an array.
(4) Removing the photoresist pattern by a liftoff process.
(5) Forming an indium gallium zinc oxide layer with a thickness greater than or equal to 50 nm and less than or equal to 100 nm on a layer where the first electrodes 101 are located.
(6) Coating photoresist on the indium gallium zinc oxide layer, and photoetching and developing the photoresist to pattern the photoresist, to obtain a photoresist pattern for making the semiconductor layer 102.
(7) Etching the indium gallium zinc oxide layer by using the photoresist pattern as a mask to form semiconductor layers 102 stacked in a one-to-one correspondence with the first electrodes 101.
(8) Removing the photoresist pattern by a liftoff process.
(9) Spin-coating a cadmium selenide/zinc sulfide quantum dot layer with a thickness greater than or equal to 50 nm and less than or equal to 70 nm on each semiconductor layer 102, and baking the cadmium selenide/zinc sulfide quantum dot layer at a temperature greater than or equal to 90° C. and less than or equal to 130° C. until finalized.
(10) Forming an indium tin oxide layer with a thickness greater than or equal to 70 nm and less than or equal to 140 nm on the cadmium selenide/zinc sulfide quantum dot layer.
(11) Coating photoresist on the indium tin oxide layer, and photoetching and developing the photoresist to pattern the photoresist, to obtain a photoresist pattern for making the intrinsic absorption layer 103 and the second electrode 104.
(12) Etching the indium tin oxide layer and the cadmium selenide/zinc sulfide quantum dot layer by using the photoresist pattern as a mask to form the intrinsic absorption layers 103 and the second electrodes 104 that are in a one-to-one correspondence with the semiconductor layers 102.

It should be understood that since the manufacturing process of other film layers in the detection substrate is the same as that in the related art, it is not described in this disclosure.

In the second type of detection substrate, the material of the first electrode 101 of the photoelectric detector is graphene, the material of the semiconductor layer 102 is polysilicon, the material of the intrinsic absorption layer 103 is lead sulfide quantum dots, and the material of the second electrode 104 is indium tin oxide, the corresponding manufacturing process is as follows.
(1) Forming graphene (such as a single-layer graphene) on the base substrate 100 by a transfer process, and the thickness of the graphene is greater than 0 nm and less than or equal to 1 nm.
(2) Coating photoresist on the graphene, and photoetching and developing the photoresist to pattern the photoresist, to obtain a photoresist pattern for making the first electrode 101.
(3) Etching the graphene by using the photoresist pattern as a mask, to form a plurality of first electrodes 101 arranged in an array.
(4) Removing the photoresist pattern by a liftoff process.
(5) Forming an amorphous silicon (a-Si) layer with a thickness greater than or equal to 50 nm and less than or equal to 100 nm by a chemical vapor deposition method (such as PECVD) on the layer where the first electrodes 101 are located.
(6) Annealing the amorphous silicon layer at 400° C. for 1 hour, and performing Excimer Laser Annealing (ELA) crystallization treatment on the amorphous silicon layer to form a polycrystalline silicon layer.
(7) Coating photoresist on the polysilicon layer, and photoetching and developing the photoresist to pattern the photoresist, to obtain a photoresist pattern for making the semiconductor layer 102.
(8) Wet etching the polysilicon layer by using the photoresist pattern as a mask, to form semiconductor layers 102 stacked in a one-to-one correspondence with the first electrodes 101.
(9) Removing the photoresist pattern by a liftoff process.
(10) Spin-coating a lead sulfide quantum dot layer with a thickness greater than or equal to 50 nm and less than or equal to 70 nm on each semiconductor layer 102, and baking the lead sulfide quantum dot layer at a temperature greater than or equal to 90° C. and less than or equal to 130° C. until finalized.
(11) Forming an indium tin oxide layer with a thickness greater than or equal to 70 nm and less than or equal to 140 nm on the lead sulfide quantum dot layer.
(12) Coating photoresist on the indium tin oxide layer, and photoetching and developing the photoresist to pattern the photoresist, to obtain a photoresist pattern for making the intrinsic absorption layer 103 and the second electrode 104.
(13) Etching the indium tin oxide layer and the lead sulfide quantum dot layer by using the photoresist pattern as a mask, to form the intrinsic absorption layers 103 and the second electrodes 104 that are in a one-to-one correspondence with the semiconductor layers 102.

It should be understood that since the manufacturing process of other film layers in the detection substrate is the same as that in the related art, it is not described in this disclosure.

In the third type of detection substrate, the first electrode 101 and the second electrode 104 of the photoelectric detector form an interdigitated electrode, the material of the interdigitated electrode are stacked titanium metal and palladium metal, the material of the semiconductor layer 102 and the intrinsic absorption layer 103 is cadmium selenide/zinc sulfide quantum dots, the material of the active layer 105 is indium gallium zinc oxide, and the corresponding manufacturing process is as follows.
(1) Washing and drying the base substrate 100 (such as a glass substrate) by a standard process.
(2) Forming a titanium metal layer with a thickness greater than or equal to 5 μm and less than or equal to 10 μm on the base substrate 100 by using an electron beam evaporation process, and forming a palladium metal layer with a thickness greater than or equal to 40 μm and less than or equal to 200 μm on the titanium metal layer.
(3) Coating photoresist on the palladium metal layer, and photoetching and developing the photoresist to pattern the photoresist, to obtain a photoresist pattern for making the first electrode 101 and the second electrode 104, the photoresist pattern forms an interdigital pattern, the finger width is greater than or equal to 3 μm and less than or equal to 15 μm, and the finger spacing is greater than or equal to 5 μm and less than or equal to 30 μm.
(4) Etching the stacked titanium metal layer and palladium metal layer by using the photoresist pattern as a mask, to form the first electrodes 101 and the second electrodes 104 of an interdigital structure.
(5) Removing the photoresist pattern by using a liftoff process.
(6) Spin-coating a cadmium selenide/zinc sulfide quantum dot layer on the interdigitated electrode, and drying it on a hot plate; the spin-coating speed is greater than or equal to 500 rpm and less than or equal to 3000 rpm, and the spin-coating time is greater than or equal to 30 s and less than or equal to 60 s, the baking temperature is greater than or equal to 100° C. and less than or equal to 150° C., and the baking time is greater than or equal to 5 mins and less than or equal to 20 mins.
(7) Coating photoresist on the cadmium selenide/zinc sulfide quantum dot layer, and photoetching and developing the photoresist to pattern the photoresist, to obtain a photoresist pattern for making the semiconductor layer 102 in the interdigital region.
(8) Etching the cadmium selenide/zinc sulfide quantum dot layer by using the photoresist pattern as a mask, to form semiconductor layers 102 arranged in a one-to-one correspondence with interdigitated electrodes.
(9) Forming an indium gallium zinc oxide layer with a thickness greater than or equal to 30 nm and less than or equal to 100 nm on the semiconductor layer 102 by a magnetron sputtering process.
(10) Coating photoresist on the indium gallium zinc oxide layer, and photoetching and developing the photoresist to pattern the photoresist, and to obtain a photoresist patterning for making the active layer in the interdigital region.
(11) Etching the indium gallium zinc oxide layer by using the photoresist pattern as a mask, to form active layers 105 corresponding to the interdigitated electrodes in a one-to-one correspondence.
(12) Spin-coating the cadmium selenide/zinc sulfide quantum dot layer on the active layer 105, and drying it on a hot plate; the spin-coating speed is greater than or equal to 500 rpm and less than or equal to 3000 rpm, and the spin-coating time is greater than or equal to 30 s and less than or equal to 60 s, the baking temperature is greater than or equal to 100° C. and less than or equal to 150° C., and the baking time is greater than or equal to 5 mins and less than or equal to 20 mins.
(13) Coating photoresist on the cadmium selenide/zinc sulfide quantum dot layer, and photoetching and developing the photoresist to pattern the photoresist, to obtain a photoresist patterning for making the intrinsic absorbing layer 103 in the interdigital region.
(14) Etching the cadmium selenide/zinc sulfide quantum dot layer by using the photoresist pattern as a mask, to form intrinsic absorption layers 103 corresponding to the interdigitated electrodes in a one-to-one correspondence.

It should be understood that since the manufacturing process of other film layers in the detection substrate is the same as that in the related art, it is not described in this disclosure.

In addition, in the above manufacturing method provided by the embodiments of the present disclosure, the patterning process involved in forming each layer structure may not only include part or all of the process such as deposition, photoresist coating, masking, exposure, development, etching, photoresist removing and etc., may also include other processes, which are subject to the graphics that form the required composition during the actual manufacturing process, and are not limited here. For example, a post-baking process may also be included after development and before etching. The deposition process can be chemical vapor deposition, plasma enhanced chemical vapor deposition or physical vapor deposition, which is not limited here. The mask used in the masking process can be a half tone mask, single slit mask or gray tone mask, which is not limited here. The etching can be dry etching or wet etching, which is not limited here.

Based on the same inventive concept, the embodiments of the present disclosure provide a detection apparatus, including the above-mentioned detection substrate provided by the embodiments of the present disclosure. Since the problem-solving principle of the detection apparatus is similar to the problem-solving principle of the above-mentioned detection substrate, the implementation of the detection apparatus can refer to the above-mentioned embodiments of the detection substrate, and will not be repeated.

In some embodiments, the detection apparatus provided by the embodiments of the present disclosure may be used for identifying fingerprints, palm prints, and other lines, or for detection of X-ray imaging. In addition, other essential components in the detection apparatus should be understood by those having ordinary skill in the art, and will not be repeated here, nor should they be used as limitations on the present disclosure.

Although the preferred embodiments of the present disclosure have been described, those skilled in the art can make various changes and modifications to the embodiments of the present disclosure without departing from the spirit and scope of the embodiments of the present disclosure. In this way, if these modifications and variations of the embodiments of the present disclosure fall within the scope of the claims of the present disclosure and their equivalent technologies, the present disclosure also intends to include these modifications and variations.

What is claimed is:

1. A photoelectric detector, comprising:
a first electrode;
a semiconductor layer located on a side of the first electrode, wherein a Schottky junction is provided between the semiconductor layer and the first electrode;
an intrinsic absorption layer located on a side of the semiconductor layer away from the first electrode; and
a second electrode being opposite to the first electrode, wherein the second electrode is adjacent to one of the intrinsic absorption layer and the semiconductor layer.

2. The photoelectric detector according to claim 1, wherein the second electrode and the first electrode are arranged in different layers and opposite to each other, and the second electrode is arranged adjacent to the intrinsic absorption layer.

3. The photoelectric detector according to claim 1, wherein the second electrode is arranged opposite to the first electrode in a same layer, the second electrode is arranged adjacent to the semiconductor layer, and the second electrode and the first electrode form an interdigitated electrode.

4. The photoelectric detector according to claim 3, further comprising an active layer disposed between the semiconductor layer and the intrinsic absorption layer.

5. The photoelectric detector of claim 4, wherein an orthographic projection of the active layer on the first electrode, an orthographic projection of the semiconductor layer on the first electrode, and an orthographic projection of the intrinsic absorption layer on the first electrode are substantially coincident, and an area of the orthographic projection of the active layer on the first electrode is larger than an area of an interdigital region of the interdigitated electrode.

6. The photoelectric detector according to claim 4, wherein a material of the active layer is oxide.

7. The photoelectric detector according to claim 1, wherein a material of the first electrode comprises a metal material and/or a semi-metallic material; and
wherein the metal material is stacked titanium metal and palladium metal, and the semi-metallic material is graphene.

8. The photoelectric detector according to claim 1, wherein a material of the semiconductor layer is indium gallium zinc oxide or polysilicon.

9. The photoelectric detector according to claim 1, wherein a material of the intrinsic absorption layer is cadmium selenide/zinc sulfide quantum dots or lead sulfide quantum dots.

10. The photoelectric detector according to claim 2, wherein a material of the second electrode is a transparent conductive material.

11. The photoelectric detector according to claim 10, wherein the transparent conductive material is indium tin oxide.

12. A detection substrate, comprising:
a base substrate;
a plurality of photoelectric detectors arranged in an array on the base substrate, wherein the photoelectric detectors are the photoelectric detector according to claim 1.

13. The detection substrate according to claim 12, further comprising a plurality of transistors, a layer where the plurality of transistors are located is between the base substrate and a layer where the plurality of photoelectric detectors are located, wherein first electrodes of the transistors are electrically connected with the first electrodes in a one-to-one correspondence.

14. The detection substrate according to claim 13, further comprising a plurality of gate lines and a plurality of data lines arranged in an intersecting manner, wherein each of the plurality of gate lines is electrically connected with gates of transistors corresponding to a row of photoelectric detectors in an extending direction of the gate lines, each of the plurality of data lines is electrically connected to second electrodes of transistors corresponding to a row of photoelectric detectors in an extending direction of the data lines.

15. The detection substrate according to claim 14, wherein orthographic projections of the plurality of gate lines on the base substrate and orthographic projections of the plurality of photoelectric detectors on the base substrate do not overlap each other, orthographic projections of the plurality of data lines on the base substrate and the orthographic projections of the plurality of photoelectric detectors on the base substrate do not overlap each other.

16. The detection substrate according to claim 14, further comprising a plurality of bias-voltage lines, a layer where the plurality of bias-voltage lines are located is on a side, away from the base substrate, of a layer where the plurality of photoelectric detectors are located, wherein the plurality of bias-voltage lines are arranged in parallel with the plurality of data lines or the plurality of gate lines, and each of the plurality of bias-voltage lines is electrically connected with second electrodes of a row of the photoelectric detectors correspondingly in an extending direction of the plurality of bias-voltage lines.

17. A method for manufacturing the detection substrate, comprising:
providing a base substrate; and
forming a plurality of photoelectric detectors arranged in an array on the base substrate, wherein each of the photoelectric detectors comprise:
a first electrode;
a semiconductor layer located on a side of the first electrode, wherein a Schottky junction is provided between the semiconductor layer and the first electrode;
an intrinsic absorption layer located on a side of the semiconductor layer away from the first electrode; and
a second electrode being opposite to the first electrode, wherein the second electrode is adjacent to one of the intrinsic absorption layer and the semiconductor layer.

18. The method according to claim 17, wherein the forming a plurality of photoelectric detectors arranged in an array on the base substrate, comprises:
forming a plurality of first electrodes arranged in an array on the base substrate;
forming a semiconductor layer correspondingly on each of the plurality of first electrodes; and
forming an intrinsic absorption layer and a second electrode correspondingly on the semiconductor layer;
wherein, the first electrode, the semiconductor layer, the intrinsic absorption layer and the second electrode which are arranged correspondingly form a photoelectric detector.

19. The manufacturing method according to claim 17, wherein the forming a plurality of photoelectric detectors arranged in an array on the base substrate, comprises:
forming a plurality of first electrodes and a plurality of second electrodes on the base substrate, wherein the first electrodes are in one-to-one correspondence with the second electrodes to form interdigitated electrodes;
forming a semiconductor layer correspondingly on each of the interdigitated electrodes; and
forming an active layer and an intrinsic absorption layer correspondingly on the semiconductor layer;
wherein, the interdigitated electrode, the semiconductor layer, the active layer and the intrinsic absorption layer which are arranged correspondingly form a photoelectric detector.

20. A detection apparatus, comprising the detection substrate according to claim 12.
